(19) United States
(12) Patent Application Publication
(10) Pub. No.: US 2025/0116615 A1
(43) Pub. Date: Apr. 10, 2025

(54) EUV Microscope

(71) Applicant: EUV Tech, Inc., Martinez, CA (US)

(72) Inventors: Chami N. PERERA, Martinez, CA (US); David C. HOUSER, Martinez, CA (US); Charles G. MURRAY, Martinez, CA (US); Alexander N. KHODAREV, Martinez, CA (US); Travis W. GRODT, Martinez, CA (US)

(21) Appl. No.: 18/982,069

(22) Filed: Dec. 16, 2024

Related U.S. Application Data
(63) Continuation of application No. 17/893,862, filed on Aug. 23, 2022, now Pat. No. 12,203,874.
Application No. 17/893,862 is a continuation-in-part of application No. 17/503,071, filed on Oct. 15, 2021, now Pat. No. 11,960,202.

(51) Int. Cl. G01N 21/956; G03F 7/00

(52) U.S. Cl. CPC G01N 21/956; G03F 7/70608; G03F 7/7085; G01N 2021/95676

(57) ABSTRACT

An EUV microscope apparatus utilizing a source of EUV light. The light is sent to a collector which creates a first focused EUV beam. A monochromator module receives the first focused EUV beam and produces a second focused EUV beam that is passed to an illumination module. The output of the illumination module is reflected off a mask. The reflected beam from the mask is sent to a zone-plate and a detector to produce an image.

### CROSS-REFERENCES TO RELATED APPLICATIONS

The present application is a Continuation-In-Part of U.S. patent application Ser. No. 17/503,071, filed 15 Oct. 2021.

### BACKGROUND OF THE INVENTION

The present application relates to a novel and useful EUV mask imaging tool or extreme ultraviolet (EUV) microscope, for use with EUV lithography masks used to produce electronic chips.

Prior EUV mask imaging devices have been proposed to assess the quality of EUV masks. For example, U.S. Pat. No. 6,738,135 depicts a novel system for inspecting lithography masks that are sometimes referred to as zone-plate microscopes.

It is realized that zone-plate microscopes are highly chromatic, having a wave-length dependent focal length. If not controlled, this characteristic leads to poor resolution. Since chromatic effects are focal-length dependent, the shorter the focal length of these devices, the less important chromatic effects become.

In U.S. Pat. No. 6,738,135, a sufficiently short focal length was achieved in order to handle the full typical bandwidth supported by Mo/Si multilayer optics. Although successful, certain drawbacks existed. Namely, the system working distance of this prior art device was severely constrained. Moreover, the corrective implementation of a zone-plate central stop to filter out zone-plate zero order flare may not be used, since at short working distances, the central stop of such cone-plate would occupy too large a fraction of the full light aperture to be viable.

An EUV microscope apparatus for analyzing EUV masks in an efficient manner would constitute a notable advance in the electronic arts.

### SUMMARY OF THE INVENTION

In accordance with the present application, the above delineated problems are solved by using a monochromator which further narrows the bandwidth of the generated EUV beam and, thus, allows for a longer working distance.

The EUV mask imaging tool apparatus includes as one of its elements a source of a beam or emanation of EUV light. Such emanation may originate with a laser-produced plasma, a discharged-produced plasma, and the like. The beam of EUV light is forwarded to an optional collector which produces a first focused EUV beam. The optional collector is formed of two mirrors with optical power in series. For example, the collector may include a flat mirror in combination with an elliptical or aspherical mirror. In addition, the collector may take the form of a single mirror, such as a spherical, elliptical, or aspherical mirror. The beam leaving the collector serves as an intermediate focus to subsequent elements of the apparatus of the present application.

First intermediate focused EUV beam from the optional collector passes to a monochromator having entrance and exit slits. Such EUV beam is forwarded to the monochromator, either directly or by way of an intermediate focus produced by the optional collector. The entrance slit of the monochromator can be excluded if the intermediate focus size or real source size is itself smaller that the required entrance slit size. In certain cases, the monochromator itself may be comprised of glancing and/or near normal optics and should ideally include a dispersing element. In essence, when used without a separate collector, the monochromator operates as a condenser and no intermediate focus of the EUV beam from the EUV source is formed. The monochromator is then used to purify the light to the level of λ/Δλ of 350 or better. Thus, a second focused EUV beam passes from the monochromator.

The second focused purified EUV beam from the monochromator is sent to an illumination module or illuminator. Illumination module concentrates the EUV beam leaving the monochromator and directs such EUV beam to the surface of the mask being analyzed. In essence, the illumination module controls the average and angular extent of the light illuminating the mask. In certain cases, the monochromator also functions as the illuminator, obviating the need for a separate illumination module.

The EUV light reflected from the mask passes through a zone-plate. The zone-plate may, optionally, include a central obscuration in order to employ first order light without overlap of zero order light. The light passing through the zone-plate is sent as an image to a detector such as a charge coupled device (CCD) which normally includes a screen where the EUV reflective characteristics of the mask may be viewed by the user. The image may be recorded for subsequent viewing and/or analysis by the user or by automated computer software.

Thus, a novel EUV mask imaging tool is provided which features the use of a non-synchrotron source that delivers partially coherent or incoherent EUV light to an integrated monochromator and a zone-plate having a central stop to mitigate zero order flare.

It is therefore an object of the present application to provide a novel EUV mask imaging tool that efficiently and economically is capable of visualizing and evaluating EUV lithography masks.

Another object of the present application is to provide a novel EUV mask imaging tool that allows visualization and evaluation of EUV masks at a lower cost than EUV imaging/inspection tools of the prior art.

Another object of the present application is to provide a novel EUV mask imaging tool that includes a novel optical design having shorter track length and smaller, easier to maintain imaging optics that are lacking in comparable tools of the prior art.

Another object of the present application is to provide a novel EUV mask imaging tool that eliminates chromatic effects found in prior zone-plate microscopes.

Another object of the present application is to provide a novel EUV mask imaging tool which employs a zone-plate having a central stop, or obscuration, to filter out zone-plate zero order flare.

Another object of the present application is to provide a novel EUV mask imaging tool for visualizing and evaluating EUV lithography masks which is capable of measuring such masks with a high degree of accuracy and repeatability.

Another object of the present application is to provide a novel EUV mask imaging tool which is compatible with conventional mask blank transfer systems and is operational in standard clean rooms, typically used to manufacture semiconductor chips.

The invention possesses other objects and advantages especially as concerns particular characteristics and features thereof which will become apparent as the specification continues.

Reference is made to the following drawings, which further describe the application sought for patenting.

### BRIEF DESCRIPTION OF THE SEVERAL VIEWS OF THE DRAWINGS

FIG. 1 is a schematic view depicting the elements of an embodiment of the apparatus of the present application.

FIG. 2 is an isometric view showing an embodiment of the illumination module of the apparatus of the present application.

FIG. 3 is a schematic view showing the position of the zone-plate relative to a mask in the apparatus of the present application.

FIG. 4 is a schematic view illustrating the operation of the zone-plate of the apparatus of the present application.

FIG. 5 is a block diagram depicting the apparatus of the present application utilizing a collector having the combination of flat and elliptical or aspherical mirrors.

FIG. 6 is a block diagram showing another embodiment of the apparatus of the present application in which the collector utilizes only a single aspherical or elliptical mirror.

FIG. 7 shows another embodiment of the apparatus of the present application in which the illumination module takes the form of a combination of a flat and aspherical or elliptical mirror.

FIG. 8 shows another embodiment of the apparatus of the present application in which a block diagram shows the illumination module in the form of a single aspherical or elliptical mirror.

FIG. 9 shows another embodiment of the apparatus of the present application in which the monochromator produces an image without the use of a collector or illuminator.

For a better understanding of the application, reference is made to the following detailed description of the preferred embodiments which should be referenced to the above described drawings.

### DETAILED DESCRIPTION OF THE PREFERRED EMBODIMENTS

Various aspects of the present application will evolve from the following detailed description thereof which should be referenced to the prior delineated drawings.

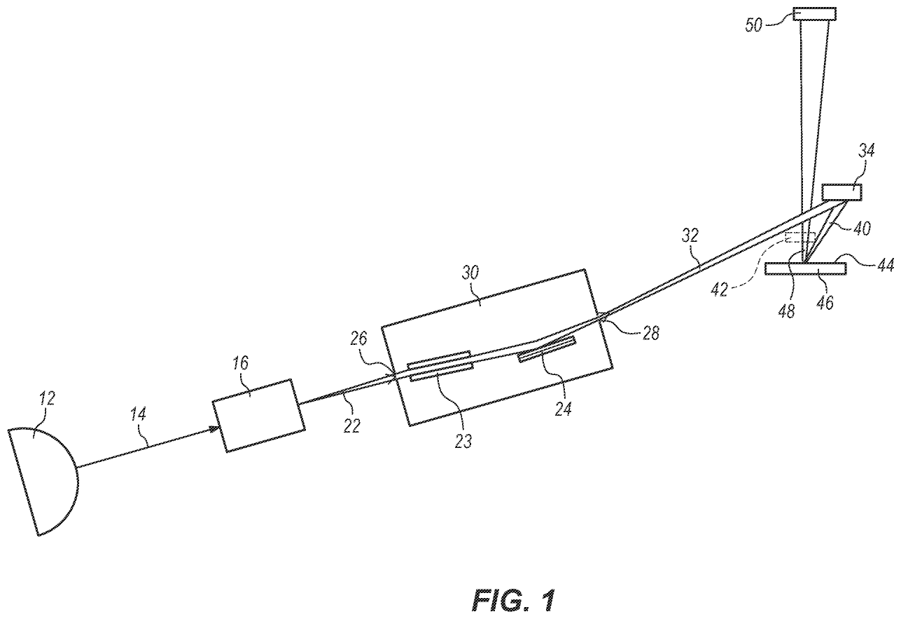

With reference to FIG. 1, reference character 10 is employed to depict the tool apparatus as a whole. Tool apparatus 10 includes as one of its elements an extreme ultraviolet (EUV) light source 12 which may be a laser produced plasma source. However, EUV light source 12 may also derive from a discharge produced plasma source and the like. The following table represents the optical specifications of tool apparatus 10:

TABLE I

| EUV wavelength | 13.5 | nm |
|---|---|---|
| EUV source type | Incoherent | |
| Illumination size | 10 | μm |
| Focal length | 625 | μm |
| Band-width (λ/Δλ) | >=350 | |
| CCD real pixel size | 13 | μm |

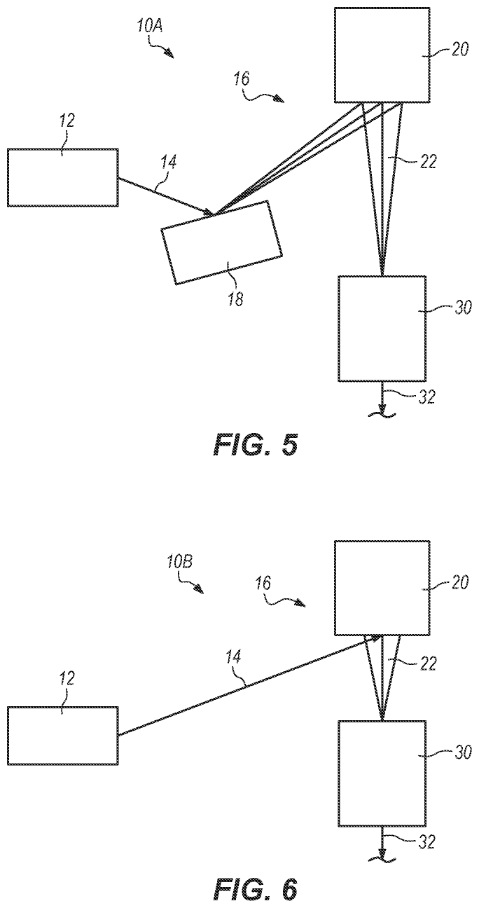

Viewing FIG. 1, an EUV beam 14 from source 12 is sent to collector 16 which may take the form of one or two or more mirrors with optical power in series. Collector 16 produces a first focused EUV beam 22. For example, collector 16 of apparatus 10A may include a flat mirror 18 in series with an aspherical or elliptical mirror 20, FIG. 5. However, collector 16 may also include only a single aspherical or elliptical mirror 20 in embodiment 10B, FIG. 6.

Viewing FIG. 1 again, the resulting first focused EUV beam 22 from collector 16 is passed to a monochromator module 30. Monochromator module 30 includes an entrance slit 26 and exit slit 28 on either side. Again, monochromator module 30, thus, performs a focusing function that is used to re-image EUV light from the entrance slit 26 to exit slit 28. In essence, monochromator module 30 is used to purify the received light to a level of λ/Δλ of 350 or better. Monochromator module 30 may take the form of any suitable device known in the art and is available, when used with the collector 16, from EUV Tech Inc. of Martinez, California, under part No. B151667. For example, monochromator module 30 may externalize one having a condenser 23 and a cylindrical grating 24 bringing the UV light to exit slit 28. A second focused EUV beam 32 passes from exit slit 28.

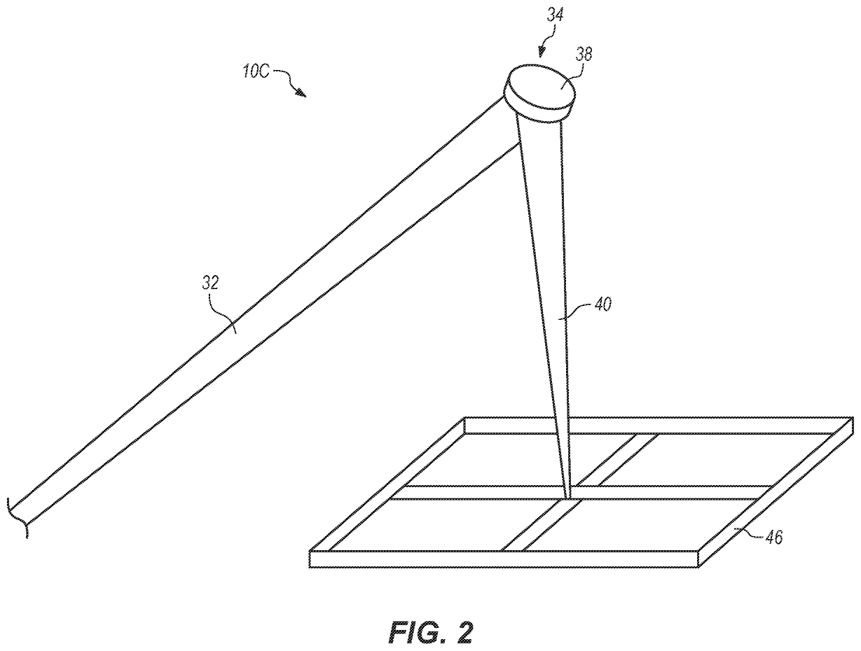

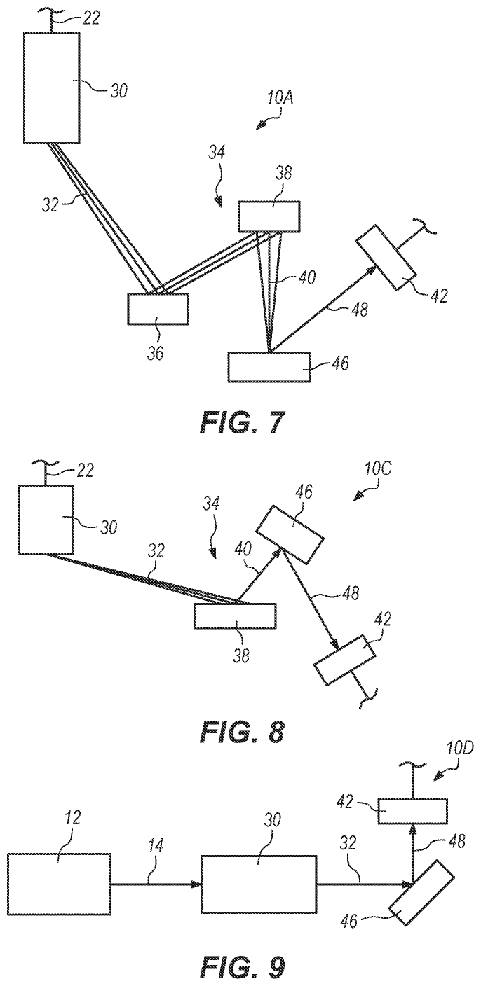

Second EUV beam 32, exiting exit slit 28, travels to an illumination module (illuminator) 34, FIG. 1. Illumination module 34 may consist, in one form in embodiment 10A, as a combination of a flat mirror 36 and an elliptical or aspherical mirror 38, FIG. 7. Illumination module 34 may also be formed by a single ellipsoidal or aspherical mirror 38 in embodiment 10C, FIGS. 2 and 8. Illumination module 34 serves both to concentrate the light leaving monochromator module 30 and to define the angular extent of the illumination. Illumination module 34 produces an illumination beam 40 having a width of about 10 μm on the mask 46.

The functionality of monochromator module 30, illumination module 34, and collector 16 may be combined into a single entity, such as monochromator module 30 in embodiment 100, FIG. 9. In this embodiment, EUV beam 32 from monochromator module 30 is passed directly to mask 46.

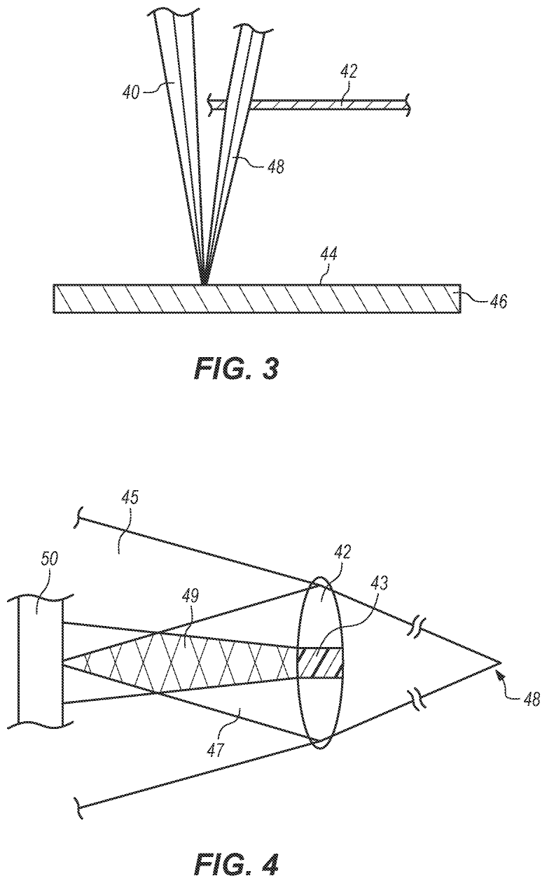

Viewing again FIG. 1, and FIGS. 3 and 4, the reimaged beam 40, leaving illumination module 34, passes through a zone-plate 42 with the aforesaid 10 um width illumination beam bearing on surface 44 of mask 46, also FIGS. 7-9. FIG. 3 depicts the position of zone-plate 42 relative to mask 46 and mask surface 44. Zone-plate 42 is shown on FIG. 4 in its functional lens shape. Light beam 48, reflected from mask 46 and passing through zone-plate 42, is sent to an imaging sensor 50 which may be an in-vacuum, cooled charge coupled device (CCD) camera, discussed in greater detail hereinafter. Again, with reference to FIG. 4, zone-plate 42 preferably includes a central obscuration 43 to prevent overlap of zero order light 45 and the diffracted first order light 47 of zone-plate 42. Central obscuration 43 creates a shadow 49 between zone-plate 42 and CCD 50. It should be noted that the diffracted first order light 47 of zone-plate 42 is the useful target imaging region of light beam 48 reflected from mask 46.

Consequently, CCD 50 serves as a detector for revealing any imperfections on surface 44 of mask 46. Such imperfections may appear as any anomalies on a screen associated with CCD 50. Charge coupled device 50 may take the form of an in-vacuum, cooled CCD manufactured by Great Eyes Gmbh of Berlin, Germany. Such CCD 50 has a pixel pitch range of: 13 μm×13 μm.

While in the foregoing embodiments of the application have been set forth in considerable detail for the purposes of making a complete disclosure of the application it may be apparent to those of skill in the art that numerous changes may be made in such details without departing from the spirit and principles of the application.

1-17. (canceled)

18. An EUV microscope apparatus for analyzing EUV masks, the apparatus comprising:
a source of EUV light;
a means for monochromatic light generation configured to receive EUV light from the source and further configured to produce an outgoing focused EUV beam of light, the outgoing focused EUV beam being directed to an EUV mask for reflection therefrom as a reflected EUV beam;
a zone-plate configured to include a central obscuration, the zone-plate being configured to receive the reflected EUV beam, and further configured to pass a certain order of the reflected EUV beam; and
a detector configured to receive the certain order of the reflected EUV beam, and further configured to produce an image thereof.

19. The apparatus of claim 18 further comprising:
a collector configured to receive EUV light from the source, wherein the collector is configured to provide a certain focused EUV beam of light, and the EUV light received by the means for monochromatic light generation comprises the certain focused EUV beam of light from the collector.

20. The apparatus of claim 18 further comprising:
an illumination module configured to intercept and reimage the outgoing focused EUV beam of light directed toward the mask, and further configured to produce a reimaged EUV beam to the mask for reflection therefrom.

21. The apparatus of claim 19 wherein the collector comprises two mirrors in series.

22. The apparatus of claim 21 wherein the collector comprises a flat mirror and an elliptical mirror in series.

23. The apparatus of claim 19 wherein the collector comprises an aspherical mirror.

24. The apparatus of claim 20 wherein the illumination module comprises two mirrors in series.

25. The apparatus of claim 18 wherein the source of EUV light comprises EUV light produced by the generation of a laser produced plasma.

26. The apparatus of claim 18 wherein the source of EUV light comprises EUV light produced by the generation of discharge produced plasma.

27. A system for analyzing EUV masks, the system comprising:
a source of EUV light;
a collector configured to receive EUV light from the source and further configured to provide a certain focused EUV beam of light;
a monochromator configured to receive EUV light from the collector and further configured to produce an outgoing focused EUV beam of light, the outgoing focused EUV beam being directed to an EUV mask for reflection therefrom as a reflected EUV beam;
a zone-plate configured to include a central obscuration, the zone-plate being configured to receive the reflected EUV beam, and further configured to pass a certain order of the reflected EUV beam; and
a detector configured to receive the certain order of the reflected EUV beam, and further configured to produce an image thereof.

28. The system of claim 27 further comprising:
an illumination module configured to intercept and reimage the outgoing focused EUV beam of light directed toward the mask, and further configured to produce a reimaged EUV beam to the mask for reflection therefrom.

29. The system of claim 28 wherein the illumination module comprises two mirrors in series.

30. The system of claim 27 wherein the collector comprises two mirrors in series.

31. The system of claim 27 wherein the collector comprises a flat mirror and an elliptical mirror in series.

32. The system of claim 27 wherein the collector comprises an aspherical mirror.

33. The system of claim 27 wherein the source of EUV light comprises EUV light produced by the generation of a laser produced plasma.

34. The system of claim 27 wherein the source of EUV light comprises EUV light produced by the generation of discharge produced plasma.

35. A method for analyzing EUV masks, the method comprising:
generating EUV light using a source of EUV light;
receiving the EUV light from the source at a means for monochromatic light generation;
producing, using the means for monochromator, an outgoing focused EUV beam of light, the outgoing focused EUV beam being directed to an EUV mask for reflection therefrom as a reflected EUV beam;
receiving the reflected EUV beam at a zone-plate including a central obscuration;
passing, using the zone-plate, a certain order of the reflected EUV beam;
receiving, at a detector, the certain order of the reflected EUV beam; and
producing, using the detector, an image based on the received certain order of the reflected EUV beam.

36. The method of claim 35 further comprising:
receiving, at a collector, EUV light from the source; and
providing, using the collector, a certain focused EUV beam of light to the means for monochromatic light generation.

37. The method of claim 35 further comprising:
intercepting and reimaging, using an illumination module, the outgoing focused EUV beam of light directed toward the mask; and
producing, using the illumination module, a reimaged EUV beam to the mask for reflection therefrom.
